(19) United States
(12) Patent Application Publication
(10) Pub. No.: US 2004/0113075 A1
(43) Pub. Date: Jun. 17, 2004

(54) Transmission electron microscope

(75) Inventor: Mikio Naruse, Tokyo (JP)

Correspondence Address: David C. Hanson, WEBB ZIESENHEIM LOGSDON ORKIN & HANSON, P.C., 700 Koppers Building, 436 Seventh Avenue, Pittsburgh, PA, 15219, US

(73) Assignee: JEOL LTD., Tokyo (JP)

(21) Appl. No.: 10/678,956

(22) Filed: Oct. 3, 2003

(30) Foreign Application Priority Data
Oct. 3, 2002 (JP) 2002-291228

(51) Int. Cl. H01J 37/22; H01J 37/26

(52) U.S. Cl. 250/311; 250/397

(57) ABSTRACT

A transmission electron microscope capable of obtaining a high-resolution, wide field-of-view TEM image corresponding to the spatial resolution of the existing transmission electron microscope is accomplished using CCD TV cameras. The microscope includes four CCD cameras, for example, having their fiber tubes tilted. The first fiber tube is tilted from a point A toward a point B. The second fiber tube is tilted from the point A toward a point E. The third fiber tube is tilted from the point A toward a point D. The fourth fiber tube is tilted from the point A toward a point C. CCD mounts are prevented from interfering with each other by tilting the fiber tubes in this way.

### BACKGROUND OF THE INVENTION

1. Field of the Invention

The present invention relates to a transmission electron microscope for taking a specimen image, which has been magnified by a projector lens system, by means of CCD TV cameras.

2. Description of Related Art

In a normal transmission electron microscope, a specimen image magnified by the projector lens system is observed with a fluorescent screen. If a desired image is observed, the fluorescent screen is moved off the optical path of the electron beam, and the image is projected onto the film in a camera chamber positioned under the fluorescent screen. The image is recorded by the photographic film.

In recent years, a TV camera tends to be installed instead of photographic film. A magnified specimen image is taken by the TV camera (for example, see Japanese Patent Laid-Open No. 139987/1994, especially page 3 and FIG. 1). A type of camera using CCD elements is used as this TV camera. FIGS. 1(a), 1(b), and 1(c) schematically shows the structure of this CCD TV camera, and in which (a) is an elevation view, (b) is a side elevation, and (c) is a front elevation. FIG. 1(d) schematically shows a transmission electron microscope fitted with this CCD TV camera.

As shown in FIG. 1(d), an electron beam emitted from an electron gun is focused onto a specimen by a condenser lens system. The beam transmitted through the specimen is focused and magnified by an objective lens, an intermediate lens, and a projector lens. A magnified specimen image is projected onto a fluorescent screen (sensitive surface) 1. The fluorescent screen 1 emits light according to the image. Light emitted according to each location on the fluorescent screen 1 is transmitted by fiber tubes 2. A CCD body 3 is coupled to an end of each fiber tube 2 and contains a number of CCD elements. The light enters these CCD elements. The CCD body 3 is held on a CCD mount 4.

Signals accumulated according to the intensity of light entering each CCD element of the CCD body 3 are read out by a CCD controller 5. The readout signals are supplied as video signals to a computer 6, which appropriately adjusts the brightness and contrast of the supplied video signals. The image projected on the fluorescent screen 1 is displayed on a display unit 7 by the computer 6.

On the above-described CCD body 3, a large number of CCD elements are arrayed on the CCD mount 4. For example, in recent CCD bodies having a maximum CCD sensitive area, 4000×4000 CCD elements are arrayed. In this kind of CCD body, the total number of pixels on the mounted CCD elements reaches 16 million (4K×4K). With such a CCD body, the pixel size is about 15 μm at 1600 pixels. The size of the field of view is 60 mm×60 mm.

It is assumed that a transmission electron microscope having a magnification of 60,000× is used. In a specimen observation region, the maximum achievable size of field of view is 1 μm×1 μm. The maximum achievable spatial resolution is 0.25 nm. With today's transmission electron microscope, however, in order to obtain a resolution better than 0.2 nm and to accept an image signal with a CCD camera with a field of view measuring 1 μm×1 μm and at that resolution, it is necessary to array 8000×8000 CCD elements on the CCD mount 4. The total number of pixels needs to be in excess of 64 million (8K×8K). With this total number of pixels, a spatial resolution of 0.13 nm can be achieved.

In order to increase the number of CCD pixels for accepting image signals, it is conceivable to array a plurality of CCD cameras. FIG. 2 shows an example in which four CCD cameras are connected, and in which (a) is an elevation view, (b) is a side elevation, and (c) is a front elevation. The shown CCD cameras are indicated by Ta, Tb, Tc, and Td, respectively. Their bodies 3a-3d, respectively, are installed on CCD mounts 4a-4d, respectively. Fiber tubes 2a-2d are respectively connected with the CCD elements of the CCD bodies.

Fluorescent materials 1a-1d acting as sensitive surfaces for detecting TEM images are connected with the front ends of the fiber tubes, respectively. The number of pixels can be increased fourfold by arraying the four CCD cameras on a plane in this way. However, as can be seen from the figures, it is required that the area of each CCD element-holding surface h of the CCD mounts 4a-4d on which the CCD bodies 3a-3d are installed be larger than each CCD body and also than the area of each fluorescent material that is identical in area with each CCD body. Therefore, it is impossible to seamlessly connect the fluorescent materials 1a-1d acting as sensitive surfaces. That is, insensitive regions 6 are present between the successive sensitive surfaces. Consequently, if the four CCD cameras are connected, the number of pixels can be increased but the produced image has missing portions. Hence, it is substantially impossible to use this apparatus.

### SUMMARY OF THE INVENTION

It is an object of the present invention to achieve a transmission electron microscope capable of obtaining a wide field-of-view TEM image at a high resolution corresponding to the spatial resolution of the existing transmission electron microscope, using CCD TV cameras.

A transmission electron microscope according to a first aspect of the present invention includes CCD detectors which have sensitive surfaces made of fluorescent material emitting light, fiber tubes for guiding the light from a respective one end thereof, a multiplicity of CCD elements connected with the other ends of the fiber tubes, and CCD mounts for holding the CCD elements. A TEM image is projected onto the sensitive surfaces made of the fluorescent material to make the fluorescent material emit the light. The light is guided into the CCD elements by the fiber tubes. The light signals are converted into electrical signals by the CCD elements. The TEM image is displayed based on the resulting electrical signals. This transmission electron microscope is characterized in that the CCD detectors are mounted such that their adjacent sensitive surfaces are connected seamlessly and that the other ends of the fiber tubes to which the CCD elements are connected are spaced from the optical axis outwardly to prevent the CCD detectors from interfering with each other.

A transmission electron microscope according to a second aspect of the invention includes CCD detectors which have sensitive surfaces made of fluorescent material emitting light, fiber tubes for guiding the light from a respective one end thereof, a multiplicity of CCD elements connected with the other ends of the fiber tubes, and CCD mounts for holding the CCD elements. A magnified and projected TEM image is directed to the sensitive surface made of the fluorescent material to make the fluorescent material emit the light. The light is guided to the CCD elements by the fiber tubes. The light signals are converted into electrical signals by the CCD elements. The TEM image is displayed based on the resulting electrical signals. This transmission electron microscope is characterized as follows. The plurality of CCD detectors are juxtaposed. An electron beam deflection means is mounted between the array of the CCD detectors and the projector lens for projecting the TEM image onto the sensitive surfaces. A desired portion of a field of view is virtually split into plural parts. The electron beam is deflected by the deflection means such that each of the split parts of the field of view hits the sensitive surface of a certain one of the CCD detectors. After gaining the image signal, the split parts of the field of view are combined.

In a further aspect of the invention, an electron beam deflection means is mounted between a single CCD detector and a projector lens for projecting a TEM image onto the sensitive surfaces. A desired portion of a field of view is virtually split into plural parts. The electron beam is deflected by the deflection means such that each of the split parts of the field of view hits the sensitive surfaces of the CCD detectors. After gaining the image signal, the split parts of the field of view are combined.

Other objects and features of the invention will appear in the course of the description thereof, which follows.

### BRIEF DESCRIPTION OF THE DRAWINGS

FIGS. 1(a), 1(b), and 1(c) schematically show the structure of a CCD TV camera;

FIG. 1(d) shows a TEM fitted with a CCD TV camera;

FIGS. 2(a), 2(b), and 2(c) show an embodiment in which four CCD cameras are connected, and comprises (a) an elevation view ,(b) a side elevation, and (c) a front elevation;

FIG. 3 illustrates an imaging apparatus used in a transmission electron microscope according to one embodiment of the invention;

FIG. 4 shows the front end of a pillar-like fiber tube of square cross section, the front end being cut obliquely;

FIG. 5 is a view of four fiber tubes whose front ends have been cut obliquely, the view being taken from the direction of the optical axis;

FIG. 6 is a view of four fiber tubes shaped such that their adjacent sides make contact with each other, the view being taken from the direction of the optical axis;

FIG. 7 illustrates an embodiment in which the sensitive surfaces of nine CCD cameras are bonded together;

FIGS. 8(a) and 8(b) illustrate an embodiment in which fiber tubes are shaped curvilinearly;

FIG. 9 is a diagram illustrating another embodiment of the invention in which four CCD cameras are coupled electrically to substantially realize a CCD camera assembly having a wider sensitive surface;

FIG. 10 is a cross section of a CCD camera, taken from the direction of the optical axis, showing its fluorescent material surface to detect image;

FIGS. 11(a), 11(b), 11(c), 11(d), and 11(e) are cross sections similar to FIG. 9, but illustrating synthesis of a field of view by deflection of an electron beam;

FIG. 12 illustrates the manner in which an electron beam is deflected to detect images having different fields of view;

FIG. 13 is a view illustrating another embodiment of the invention in which a single CCD camera is used to substantially realize a CCD camera assembly having a wider sensitive surface;

FIG. 14 is a cross section of a CCD camera, taken from the direction of the optical axis, showing its fluorescent material surface to detect image;

FIGS. 15(a), 15(b), 15(c), and 15(d) are views similar to FIG. 9, but illustrating synthesis of a field of view by deflection of an electron beam; and

FIG. 16 illustrates the manner in which an electron beam is deflected to detect images having different fields of view.

### DESCRIPTION OF THE PREFERRED EMBODIMENTS

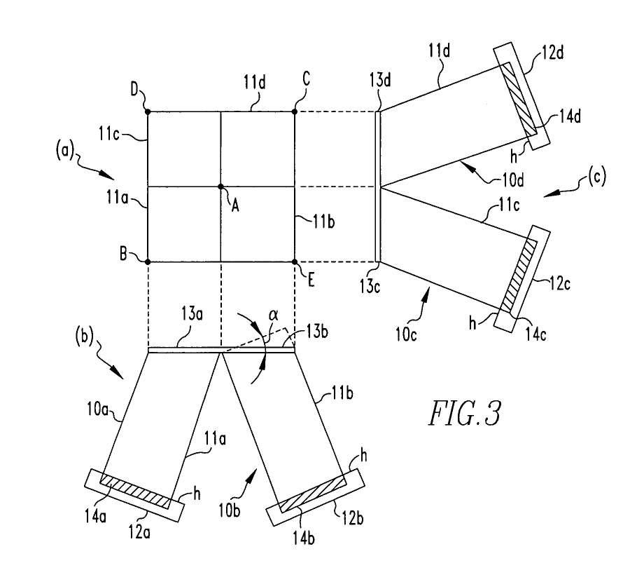

The preferred embodiments of the present invention are hereinafter described in detail with reference to the drawings. FIG. 3 shows an imaging apparatus used in a transmission electron microscope according to one embodiment of the invention. In this embodiment, there are provided four CCD cameras (CCD detectors) 10a, 10b, 10c, and 10d that are equivalent to the CCD cameras Ta, Tb, Tc, and Td shown in FIG. 2. In particular, in each CCD camera, the area of the CCD element-holding surface h is larger than the cross-sectional area of the CCD body on which the multiple CCD elements are arrayed and than the area of the sensitive surface of the fluorescent material equal in area with that cross-sectional area. In FIG. 3, portion (a) is a view of fiber tubes 11a, 11b, 11c, and 11d, as viewed from above the optical axis, portion (b) is an elevation view of the CCD cameras, and portion (c) is a side elevation of the CCD cameras.

The fiber tubes 11a, 11b, 11c, and 11d of the CCD cameras are tilted. In particular, the fiber tube 11a of the CCD camera 10a is tilted from a point A toward a point B. The fiber tube 11b of the camera 10b is tilted from the point A toward a point E. The fiber tube 11c of the camera 10c is tilted from the point A toward a point D. The fiber tube 11d of the camera 10d is tilted from the point A toward a point C. By tilting the fiber tubes in this way, CCD mounts 12a, 12b, 12c, and 12d are prevented from interfering with each other.

The front ends of the fiber tubes 11a, 11b, 11c, and 11d are successively intimately connected without any gap between them. Fluorescent materials 13a, 13b, 13c, and 13d are formed on the front ends of the fiber tubes 11a-11d, respectively. The fluorescent materials are also intimately connected without gap. The other ends of the fiber tubes 11a-11d are connected with the CCD bodies 14a-14d installed on the CCD mounts 12a-12d, respectively.

Since the fiber tubes 11a-11d are arranged obliquely relative to the planes of the fluorescent materials 13a-13d, respectively, in this way, the CCD mounts 12a-12d do not interfere with each other, if the four fluorescent materials 13a-13d are interconnected without gap. As a result, a CCD camera has an area four times as large as the area of the fluorescent materials (sensitive material) alone.

In the CCD camera constructed as described above, a TEM image is projected onto the four fluorescent materials 13a-13d and converted into light by these fluorescent materials. Light from each region on the fluorescent materials passes through a respective one of the fiber tubes 11a-11d and reaches a respective one of the sensitive surfaces of the CCD bodies 14a-14d. The light is then converted into an electrical signal corresponding to the light intensity by each CCD element and accumulated in it.

Signals accumulated in the CCD elements of the CCD bodies 14a-14d are quickly read out in turn by a controller (not shown) connected with the CCD elements (sensitive surfaces). The readout signals are then supplied as video signals to a computer. The computer combines the signals from the four CCD cameras to create one image. The image is displayed on a display device.

As mentioned so far, in a first embodiment of the invention, 8,000×8,000 CCD elements can be arrayed substantially without gap. A CCD camera assembly having a total number of pixels of 64 million (8K×8K) pixels can be built. This total number of pixels can achieve a spatial resolution of 0.13 nm.

In order to place the fiber tubes 11a-11d obliquely and to connect the fluorescent materials 13a-13d with the tubes, the fluorescent materials being laid in two dimensions at right angles to the optical axis, it is necessary to obliquely cut a front-end portion of each of the fiber tubes 11a-11d at angle a as indicated by the dotted line in FIG. 3(b).

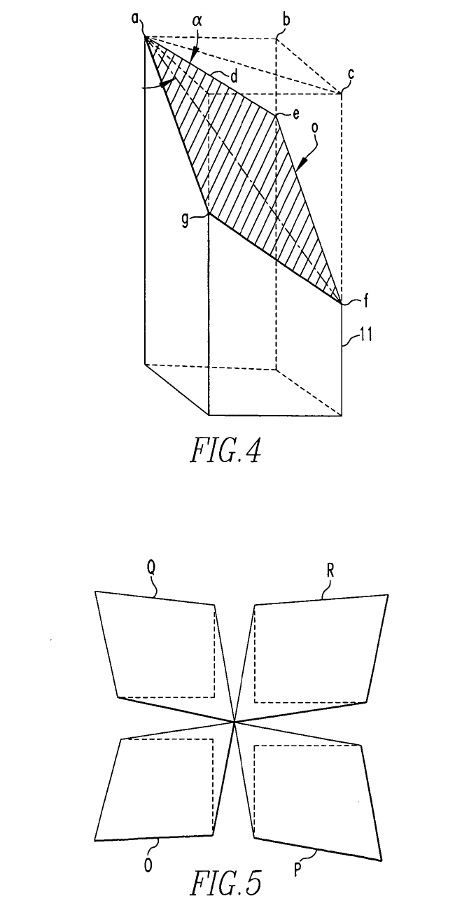

FIG. 4 shows a fiber tube 11 as a representative example of these fiber tubes 11a-11d. The cross section of this pillar-like tube assumes a rectangular form before it is cut as indicated by the dotted lines. The front end of this rectangle has vertices a, b, c, and d. After this tube is cut at angle α, the resulting vertices a, e, f, and g make a rhombic form.

After the front-end portion of the tube has been cut in this way, the hatched rhombic surface O defined by the vertices a, e, f, and g provides a surface on which a fluorescent material for each fiber tube is formed. The angle α is given by ∠ fac.

The front-end portions of the fiber tubes 11a-11d are cut at angle α, and the cut surfaces O, P, Q, and R are aligned to form a flat plane at right angles to the optical axis. As a result, the cut surfaces O, P, Q, and R assume rhombic forms whose vertices a are positioned on the optical axis when viewed from the direction of the optical axis as shown in FIG. 5. Consequently, gaps are formed between the adjacent cut surfaces. These gaps create missing portions in the final image.

For this reason, the fiber tubes are shaped such that the adjacent sides of the four cut surfaces O, P, Q, and R make contact with each other. In particular, in FIG. 5, the fiber tubes are so shaped that the cut surfaces O, P, Q, and R take forms indicated by the dotted lines. As a consequence, as shown in FIG. 6, the adjacent sides of the fiber tubes formed flatly make contact with each other. A complete final image from which any portion is not lost is obtained by forming fluorescent materials at the front ends of the four fiber tubes. When the fiber tubes are shaped, the area of the regions on which the fluorescent materials are formed decreases only slightly. A sufficient number of pixels to achieve a desired spatial resolution can be secured.

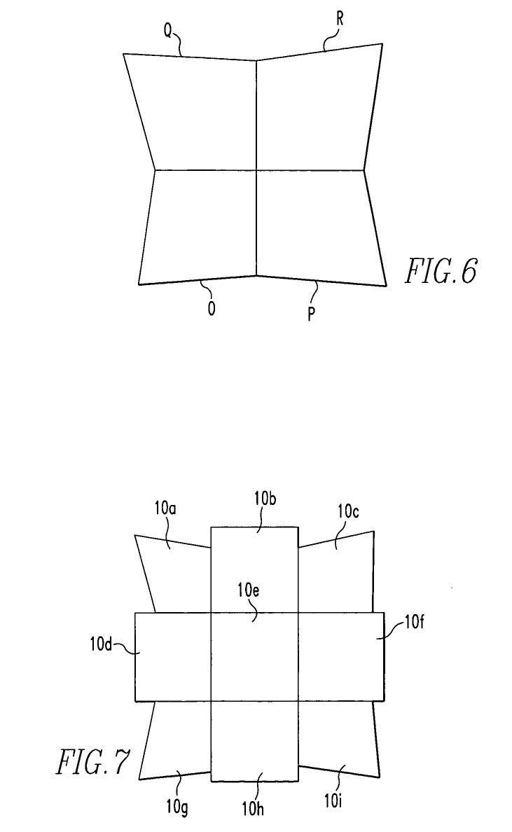

In the first embodiment described above, four CCD cameras are joined together. In the present invention, the number of used CCD cameras are not limited to four. Any arbitrary plural CCD cameras may be used. For example, in the embodiment shown in FIG. 7, nine CCD cameras 10a-10i are joined together. An image of a wider field of view and higher resolution can be obtained by increasing the number of CCD cameras in this way.

In the first embodiment, four CCD cameras are used. The fiber tubes are tilted at angle α to prevent interference between the CCD mounts. The adjacent sides of the four fluorescent materials acting as sensitive surfaces are joined seamlessly. An end portion of each fiber tube on which a fluorescent material is formed is cut obliquely. The four fluorescent materials are laid on a flat plane.

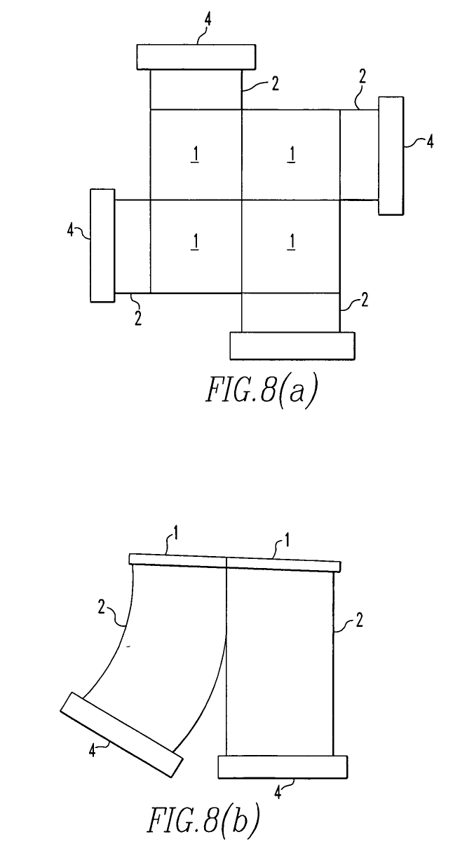

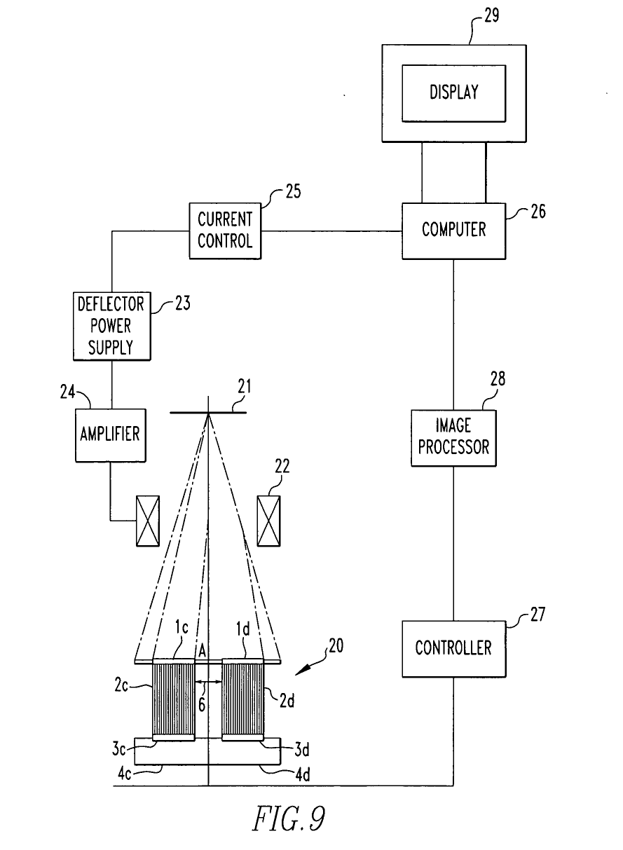

In the embodiment shown in FIGS. 8(a) and 8(b), the adjacent sides of the fluorescent materials 13a-13d of the four CCD cameras 10a-10d are joined together without gap. Also, the fiber tubes 11a-11d are shaped curvilinearly to prevent interference of the CCD bodies. In this case, it is not necessary to cut front-end portions of the fiber tubes 11a-11d obliquely.

In the first and second embodiments described above, plural CCD cameras are coupled mechanically based on the configuration where fiber tubes forming the CCD cameras are made oblique. It is also possible that four CCD cameras are coupled electrically to accomplish a CCD camera assembly having a substantially wider sensitive surface. In this case, four cameras Ta, Tb, Tc, and Td are so positioned that their CCD mounts 4a, 4b, 4c, and 4d are in contact with each other and that a square is formed as a whole as shown in FIG. 2.

Where a TEM image is taken by making use of the coupling of the four CCD cameras in this way, it is urged to make the area of the CCD element-holding surface h of each CCD mount supporting the CCD body larger than the area of each of the CCD bodies 3a, 3b, 3c, and 3d on which a multiplicity of CCD elements are mounted. As a result, insensitive regions 6 incapable of detecting image occur as shown in FIG. 2 as mentioned previously. FIG. 9 shows one example of a main portion of the imaging apparatus for use with a transmission electron microscope according to the invention.

Referring to FIG. 9, a detector 20 is used to detect a TEM image, the detector consisting of four CCD cameras coupled as shown in FIG. 2. This detector 20 is so positioned that the sensitive surfaces of the fluorescent materials, 1a, 1b, 1c, and 1d, of the CCD cameras are coincident with regions illuminated with the TEM image. In this case, the insensitive regions 6 are produced between the surfaces of fluorescent materials as mentioned previously.

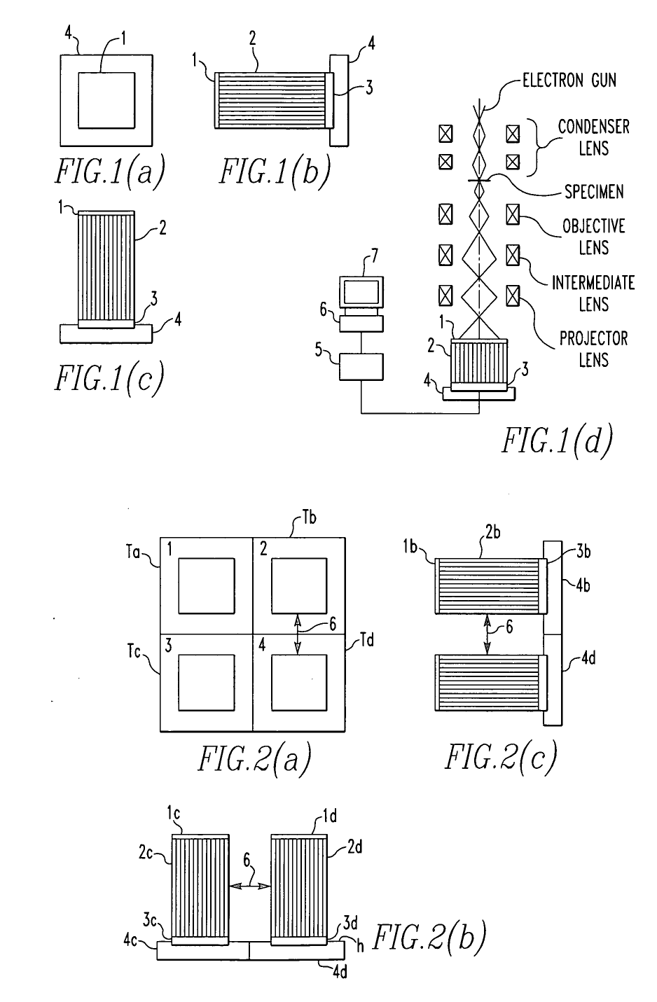

A projector lens 21 is mounted above the detector 20. A TEM image that is magnified and focused is made to hit the surfaces 1a-1d of fluorescent materials of the CCD cameras by the projector lens 21. Lenses including intermediate lenses, objective lens, and condenser lenses are positioned above the projector lens 21 as shown in FIG. 1(d).

Deflection coils 22 are mounted between the projector lens 21 and detector 20. Deflection currents are supplied to the deflection coils 22 from a deflection coil power supply 23 via a coil current amplifier 24. The power supply 23 is controlled by a deflection coil current control portion 25, which in turn is controlled by a computer 26.

When the TEM image hits the surfaces of fluorescent materials 1a-1d of the CCD cameras forming the detector 20, each portion of the fluorescent materials emits light according to the brightness of the incident image. The light emitted from each portion is guided to a respective one of the CCD bodies 3a-3d by the fiber tubes 2a-2d and converted into an electrical signal according to the intensity of the light by the multiplicity of CCD elements in the bodies.

The electrical signals converted by the multiple CCD elements are read out by the controller 27 and fed to an image processor 28. This processor 28 splices together the four images under control of the computer 26, and the resulting image is displayed on a display device 29.

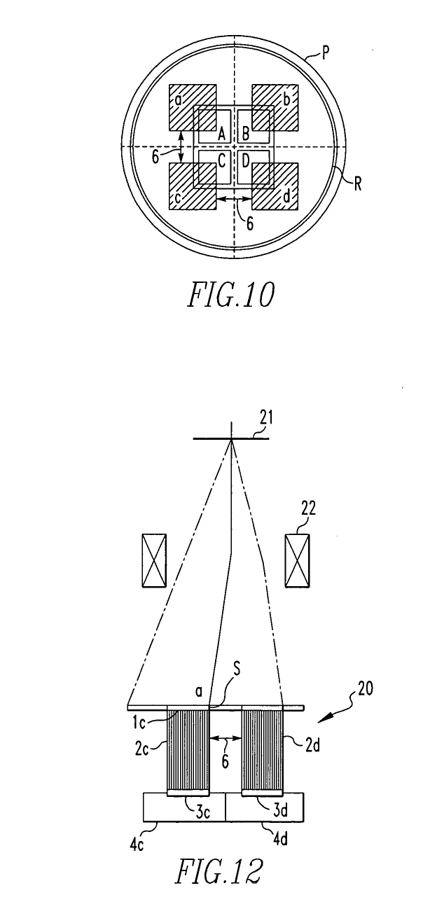

In the above-described structure, the image magnified by the projector lens 21 is projected onto the surfaces of the fluorescent materials of the detector 20. FIG. 10 is a view of the surfaces of fluorescent materials (sensitive surfaces) of the cameras 20, taken from the direction of the optical axis. A region P indicated by a single circle shows the surfaces of the cameras 20. A region R indicated by a double circle is illuminated with a TEM image. Hatched square regions a, b, c, and d are sensitive regions of the CCDs. Insensitive regions 6 that are insensitive to TEM image are present between these CCD sensitive regions.

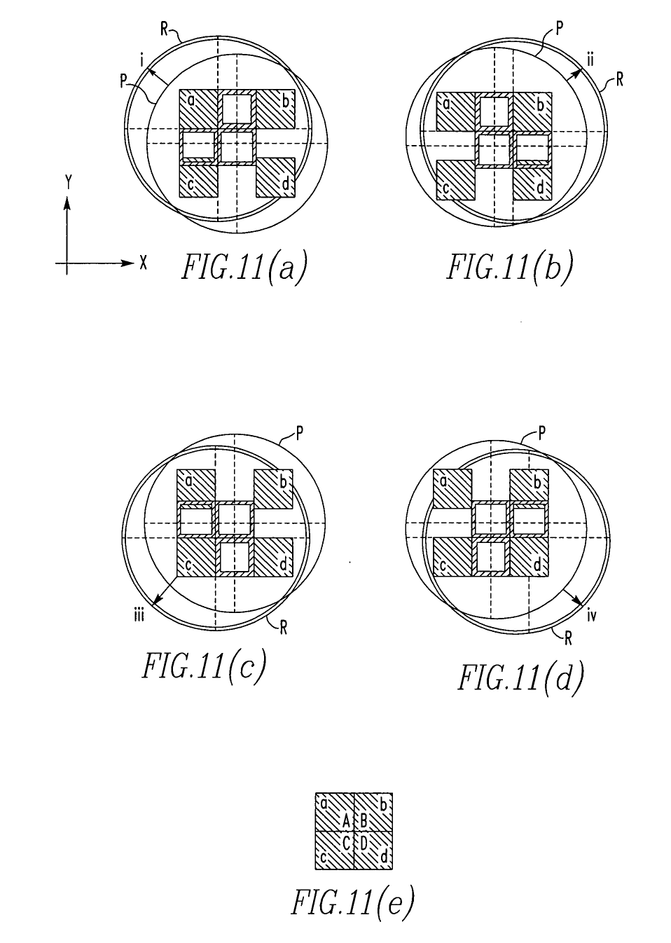

Referring still to FIG. 10, where the user wants to obtain a TEM image from a central portion, square regions A, B, C, and D delineated by double lines must be taken seamlessly. Therefore, the computer 26 controls the deflection coil current control portion 25 to excite the deflection coils 24 with a given electrical current. As shown in FIG. 11(a), the illuminated region R is deflected in the direction of the arrow i. Because of this deflection of the electron beam in the direction of the arrow i, it is possible to bring the region A and CCD detection region a into agreement with each other, out of the square regions.

Under this condition, the controller 27 reads image signals from the CCD elements contained in the CCD body 4a and supplies the signals to the image processor 28. The optical path of the beam deflected by the deflection coils 24 is shown in FIG. 12.

Then, the illuminated region R is deflected in the direction of arrow ii as shown in FIG. 11(b). Because of this deflection of the beam in the direction of the arrow ii, the region B and CCD detection region b can be brought into coincidence, out of the square regions. Under this condition, the controller 27 reads image signals from the CCD elements contained in the CCD body 4b and supplies them to the image processor 28.

Then, the illuminated region R is deflected in the direction of arrow iii as shown in FIG. 11(c). Because of this deflection, the region C and the CCD detection region c can be brought into coincidence out of the square regions. In this condition, the controller 27 reads image signals from the CCD elements contained in the CCD body 3c and supplies them to the image processor 28.

Then, the illuminated region R is deflected in the direction of arrow iv as shown in FIG. 11(d). Because of this deflection, the region D and CCD detection region d can be brought into coincidence out of the square regions. Under this condition, the controller 27 reads image signals from the CCD elements contained in the CCD body 3d and supplies them to the image processor 28.

In this way, the TEM image is deflected given distances in given directions by the deflection coils. The sensitive surfaces of the detectors are brought into coincidence with the image regions to be taken. Based on these image deflections and on signals detected by the sensitive surfaces, the image processor slices together four image signals as shown in FIG. 11(e). As a result, images of the regions A, B, C, and D are obtained and displayed on the display device 29.

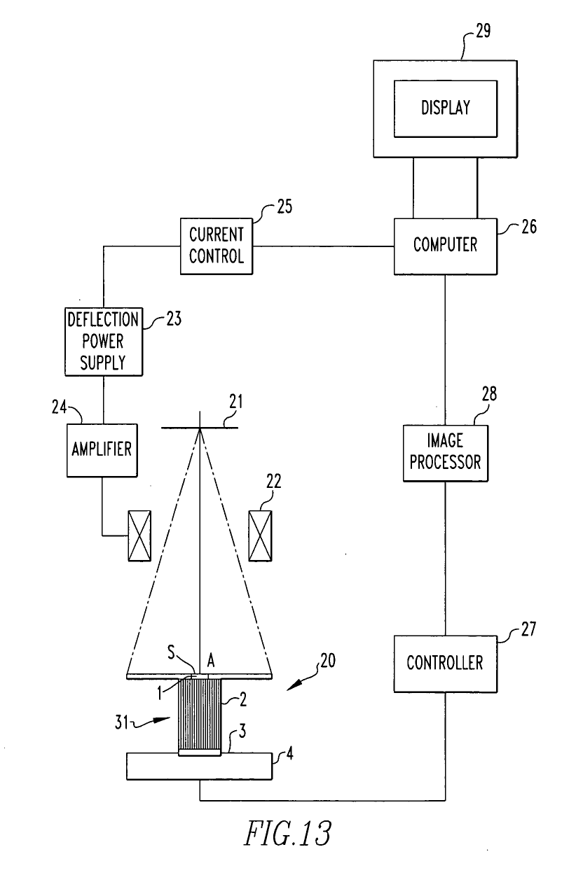

In the embodiment illustrated in FIG. 9, four CCD cameras are used and four images are spliced together. FIG. 13 shows an embodiment in which a high-resolution image having a wider angle of view is obtained using a single CCD camera 31. In both FIGS. 9 and 13, like components are indicated by like reference numerals. A TEM image detector 31 consisting of a CCD camera as shown in FIG. 1 is so positioned that the surface of the fluorescent material (sensitive surface) 1 of the CCD camera is coincident with the region illuminated with a TEM image.

A projector lens 21 is mounted above the detector 31. A TEM image magnified and focused is made to hit the surface 1 of fluorescent material of the CCD camera by the projector lens 21. Lenses including intermediate lenses, objective lens, and condenser lenses are positioned above the projector lens 21 as shown in FIG. 1(d).

Deflection coils 22 are mounted between the projector lens 21 and detector 31. Deflection currents are supplied to the deflection coils 22 from a deflection coil power supply 23 via a coil current amplifier 24. The power supply 23 is controlled by a deflection coil current control portion 25, which in turn is controlled by a computer 26.

When the TEM image hits the surface of fluorescent material 1 of the CCD camera forming the detector 31, each portion of the fluorescent material 1 emits light according to the brightness of the incident image. The light emitted from each portion is guided to the CCD body 3 by the fiber tube 2 and converted into an electrical signal according to the intensity of the light by a multiplicity of CCD elements in the body.

The electrical signals converted by the multiple CCD elements are read out by the controller 27 and fed to an image processor 28. This processor 28 splices together the four images under control of the computer 26, and the resulting image is displayed on a display device 29.

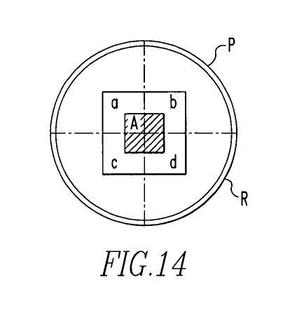

In the above-described structure, an image magnified by the projector lens 21 is projected onto the surface of the fluorescent material of the detector 31. FIG. 14 is a view of the surface of fluorescent material 1 (sensitive surface) of the camera 31, taken from the direction of the optical axis. A region P indicated by the single circle shows the fluorescent screen on the surface of the camera 31. A region R indicated by the double circle is illuminated with a TEM image.

A hatched square region A indicates the sensitive portions formed by CCD elements which are used to detect an image. To give a measure of the image detectable region, the TEM image-illuminated region S of the fluorescent screen is pressed into a square form. In this embodiment, of the image projected on the fluorescent screen, four regions a, b, c, and d indicated by squares are moved into the sensitive surface of the region A and recorded.

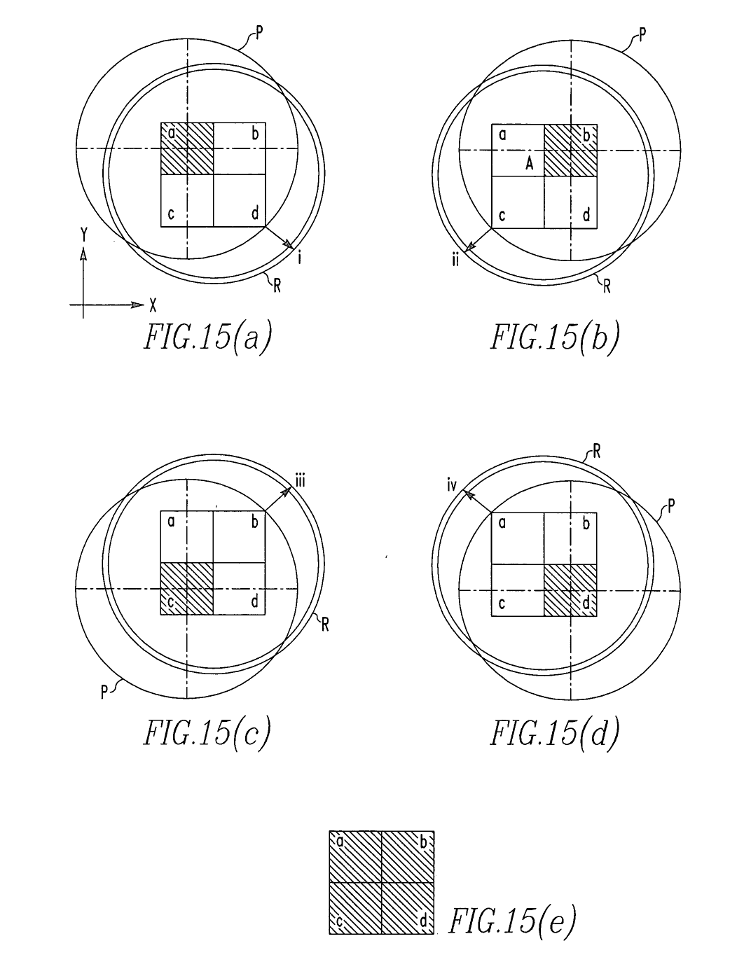

Referring still to FIG. 14, when the user wants to obtain a TEM image of the central regions a, b, c, d, the computer 26 controls the deflection coil current control portion 25 to excite the deflection coils 24 with a given current. As shown in FIG. 15(a), the region R illuminated with a TEM image is deflected in the direction of arrow i. Because of this deflection, the image detection region A and the region a are brought into coincidence out of the square regions.

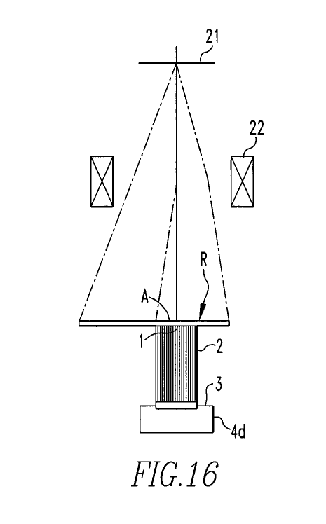

Under this condition, the controller 27 reads image signals from the CCD elements contained in the CCD body 4 and supplies them to the image processor 28. The optical path of the beam deflected by the deflection coils 24 is shown in FIG. 16.

Then, the illuminated region R is deflected in the direction of arrow ii as shown in FIG. 15(b). Because of this deflection, region b and CCD detection region A can be brought into coincidence out of the square regions. Under this condition, the controller 27 reads image signals from the CCD elements contained in the CCD body 4 and supplies them to the image processor 28.

The illuminated region R is then deflected in the direction of arrow iii as shown in FIG. 15(c). As a result, the region c and CCD detection region A can be brought into coincidence out of the square regions. Under this condition, the controller 27 reads image signals from the CCD elements contained in the CCD body 4 and supplies them to the image processor 28.

The illuminated region R is then deflected in the direction of arrow iv as shown in FIG. 15(d). As a result, the region d and CCD detection region A can be brought into coincidence out of the square regions. Under this condition, the controller 27 reads image signals from the CCD elements contained in the CCD body 4 and supplies them to the image processor 28.

In this way, a TEM image is deflected given distances in given distances by the deflection coils and brought into coincidence with image regions a, b, c, and d in turn, the regions a-d being obtained by virtually dividing the image detection surface A on the fluorescent screen P. An image of each region is detected by the controller 27. The obtained four image signals are spliced together by the image processor 28 as shown in FIG. 15(e). As a result, an image from the regions a-d is obtained. This image is displayed on the display device 29.

While preferred embodiments of the present invention have been described so far, it is to be understood that the invention is not limited thereto but rather various changes and modifications are possible. For example, the number of CCD detectors is not limited to four or nine. The invention can be applied to every case where an arbitrary number of CCD detectors are coupled. Furthermore, in FIGS. 3, 7, and 8, not all the CCD detectors need to be placed obliquely. Some of the CCD detectors may be mounted vertical to the optical axis if interference between the CCD mounts does not occur.

As described so far, the present invention makes it possible to observe a wide field of view on a specimen at a high resolution.

Having thus described my invention with the detail and particularity required by the Patent Laws, what is desired protected by Letters Patent is set forth in the following claims.

The invention claimed is:

1. A transmission electron microscope comprising:
CCD detectors which have sensitive surfaces made of fluorescent material emitting light, fiber tubes for guiding said light from a respective one end thereof, a multiplicity of CCD elements connected with the other ends of the fiber tubes, and CCD mounts for holding the CCD elements, wherein
(A) a TEM image is projected onto the sensitive surfaces made of the fluorescent material to make the fluorescent material emit the light;
(B) the light is guided into the CCD elements by the fiber tubes and converted into electrical signals by the CCD elements;
(C) the TEM image is displayed based on the resulting electrical signals; and
(D) said CCD detectors are mounted such that their adjacent sensitive surfaces are connected seamlessly and that the other ends of the fiber tubes to which the CCD elements are connected are spaced from an optical axis outwardly to prevent the CCD detectors from interfering with each other.

2. The transmission electron microscope of claim 1, wherein each of the fiber tubes having the fluorescent material at its one end is placed obliquely with respect to the optical axis, and wherein an end portion of each fiber tube on which the fluorescent material is formed is cut obliquely and the cut sensitive surfaces of the fiber tubes are connected.

3. The transmission electron microscope of claim 2, wherein an end portion of each fiber tube on which the fluorescent material is formed is cut obliquely, and wherein end surfaces of the fiber tubes are scraped such that the cut sensitive surfaces are connected seamlessly.

4. The transmission electron microscope of claim 1, wherein the sensitive surfaces of the plural CCD detectors are connected seamlessly, and wherein the fiber tubes are bent outwardly from the optical axis.

5. The transmission electron microscope of any one of claims 1 to 4, wherein each of the CCD mounts has a CCD element-holding surface that is larger in size than the sensitive surface of the fluorescent material, and wherein the other ends of the fiber tubes to which the CCD mounts are connected are spaced outwardly from the optical axis to prevent the CCD mounts from interfering with each other.

6. A transmission electron microscope comprising:
CCD detectors which have sensitive surfaces made of fluorescent material emitting light, fiber tubes for guiding said light from a respective one end thereof, a multiplicity of CCD elements connected with the other ends of the fiber tubes, and CCD mounts for holding the CCD elements, wherein
(A) a magnified and projected TEM image is guided onto the sensitive surfaces made of the fluorescent material to make the fluorescent material emit the light;
(B) the light is guided into the CCD elements by the fiber tubes and converted into electrical signals by the CCD elements;
(C) the TEM image is displayed based on the resulting electrical signals;
(D) the CCD detectors are juxtaposed;
(E) an electron beam deflection means is mounted between the array of the CCD detectors and the projector lens for projecting the TEM image onto the sensitive surface;
(F) a desired portion of a field of view is virtually split into plural parts;
(G) the electron beam is deflected by the deflection means such that each of the split parts of the field of view hits the sensitive surface of a certain one of the CCD detectors; and
(H) after gaining an image signal, the split parts of the field of view are combined.

7. A transmission electron microscope comprising:
CCD detectors which have sensitive surfaces made of fluorescent material emitting light, fiber tubes for guiding said light from a respective one end thereof, a multiplicity of CCD elements connected with the other ends of the fiber tubes, and CCD mounts for holding the CCD elements, wherein
(A) a magnified and projected TEM image is guided onto the sensitive surfaces made of the fluorescent material to make the fluorescent material emit the light;
(B) the light is guided into the CCD elements by the fiber tubes and converted into electrical signals by the CCD elements;
(C) the TEM image is displayed based on the resulting electrical signals;
(D) an electron beam deflection means is mounted between a single CCD detector and a projector lens for projecting the TEM image onto the sensitive surfaces;
(E) a desired portion of a field of view is virtually split into plural parts;
(F) the electron beam is deflected by the deflection means such that each of the split parts of the field of view hits the sensitive surfaces of the CCD detectors; and
(G) after gaining an image signal, the split parts of the field of view are combined.
